(19) United States
(12) Patent Application Publication
(10) Pub. No.: US 2025/0246545 A1
(43) Pub. Date: Jul. 31, 2025

(54) SEMICONDUCTOR STRUCTURE AND METHOD FOR FORMING THE SAME

(71) Applicant: Winbond Electronics Corp., Taichung City (TW)

(72) Inventors: Yu-Ting CHU, Taichung City (TW); Yu-Jen LIN, Taichung City (TW)

(21) Appl. No.: 18/617,979

(22) Filed: Mar. 27, 2024

(30) Foreign Application Priority Data
Jan. 29, 2024 (TW) 113103249

(51) Int. Cl. H01L 23/528; H01L 21/762; H01L 21/768; H01L 23/532

(52) U.S. Cl. CPC H01L 23/5283; H01L 21/76224; H01L 21/76819; H01L 23/528; H01L 23/5329

(57) ABSTRACT

A semiconductor structure is provided. The semiconductor structure includes a dielectric layer, a conductive layer, and at least one support pillar. The conductive layer is disposed in the dielectric layer, and the support pillar is disposed in the dielectric layer and outside the conductive layer.

### CROSS REFERENCE TO RELATED APPLICATIONS

This Application claims priority of Taiwan Patent Application No. 113103249, filed on Jan. 29, 2024, the entirety of which is incorporated by reference herein.

### BACKGROUND OF THE INVENTION

### Field of the Invention

The present disclosure relates to a semiconductor structure and a method for forming the same, and in particular, it relates to a semiconductor structure that includes a support pillar and a method for forming the same.

### Description of the Related Art

With the advancement of technology, semiconductor structures have been widely applied in various electronic devices. Due to the recent trend of miniaturizing electronic device sizes and scaling manufacturing processes, the process of manufacturing semiconductor structures often faces many challenges.

For example, chemical mechanical polishing (CMP) is commonly used to remove parts of the dielectric material and the conductive material simultaneously in the process of manufacturing the conductive layer of a semiconductor structure. The process is stopped after a certain amount of dielectric material has been removed. However, this process often results in dishing in the conductive layer, which in turn leads to subsequent connection issues (e.g., formation of open circuits).

Since the outcomes of CMP are primarily determined by the properties of the slurry, and it is difficult to change the properties of the slurry, it may be a struggle to employ existing semiconductor structures and their formation methods to improve the issue of dishing in the conductive layer.

### BRIEF SUMMARY OF THE INVENTION

The embodiments of the present disclosure provide a semiconductor structure that includes a support pillar and a method for forming the same. Based on the polishing selectivity of the slurry for the dielectric layer and the support pillar, it is possible to improve the issue of dishing in the conductive layer. This effectively improves subsequent connection issues, thereby enhancing the overall quality of the semiconductor structure.

Some embodiments of the present disclosure provide a semiconductor structure. The semiconductor structure includes a dielectric layer, a conductive layer, and at least one support pillar. The conductive layer is disposed in the dielectric layer, and the support pillar is disposed in the dielectric layer and outside the conductive layer.

Some embodiments of the present disclosure provide a method for forming a semiconductor structure. The method for forming the semiconductor structure includes the following steps. A dielectric material is formed. The dielectric material is patterned to form at least one first trench. A support pillar is formed in the first trench. A portion of the dielectric material is removed to form a dielectric layer that has a second trench, wherein the support pillar is disposed outside the second trench. A conductive layer is formed in the second trench.

### BRIEF DESCRIPTION OF THE DRAWINGS

FIG. 1 is a partial cross-sectional view illustrating the semiconductor structure according to some embodiments of the present disclosure.

FIG. 2A is a partial top view illustrating the semiconductor structure according to some embodiments of the present disclosure.

FIG. 2B is a partial top view illustrating the semiconductor structure according to some other embodiments of the present disclosure.

FIG. 3A to FIG. 3G illustrate partial cross-sectional views of forming the semiconductor structure at various stages according to some embodiments of the present disclosure.

FIG. 4A to FIG. 4B illustrate partial cross-sectional views from the stage shown in FIG. 3G to an intermediate stage leading to FIG. 1 according to some embodiments of the present disclosure.

FIG. 5 is a partial cross-sectional view illustrating the semiconductor structure according to some embodiments of the present disclosure.

### DETAILED DESCRIPTION OF THE INVENTION

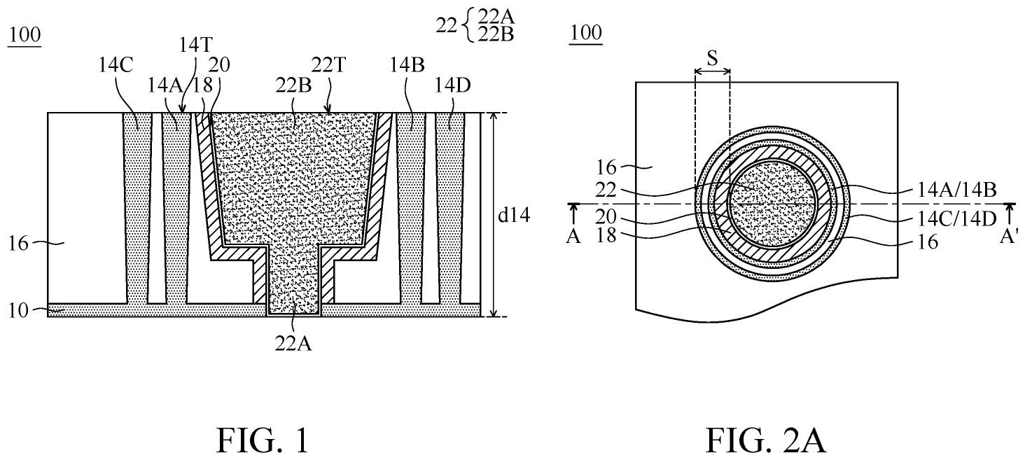

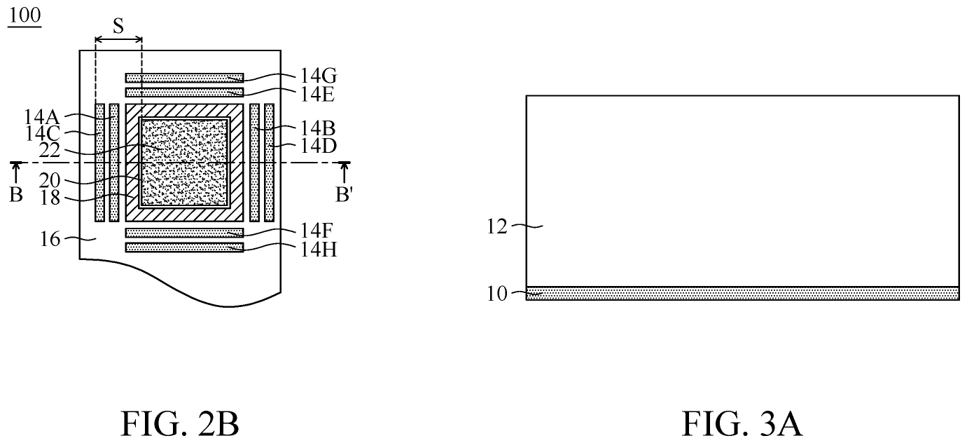

FIG. 1 is a partial cross-sectional view illustrating the semiconductor structure 100 according to some embodiments of the present disclosure. FIG. 2A is a partial top view illustrating the semiconductor structure 100 according to some embodiments of the present disclosure. FIG. 2B is a partial top view illustrating the semiconductor structure 100 according to some other embodiments of the present disclosure. For example, the semiconductor structure 100 shown in FIG. 1 may be a cross-sectional view taken along line A-A′ in FIG. 2A, or along line B-B′ in FIG. 2B, but the present disclosure is not limited thereto. It should be noted that some components of the semiconductor structure 100 have been omitted in FIG. 1, FIG. 2A, and FIG. 2B for the sake of brevity.

Referring to FIG. 1, FIG. 2A, and FIG. 2B, the semiconductor structure 100 includes an isolation layer 10 and a dielectric layer 16 disposed on the isolation layer 10. The semiconductor structure 100 also includes a conductive layer 22 and at least one support pillar (e.g., support pillars 14A, 14B, 14C, and/or 14D). The conductive layer 22 is disposed in the dielectric layer 16, and the support pillars 14A, 14B, 14C, and 14D are disposed in the dielectric layer 16 and outside the conductive layer 22. In some embodiments, the support pillars surround the conductive layer 22.

The isolation layer 10 may include a silicon-containing nitride (SiₓN_{y}), such as silicon nitride (SiN) or silicon carbonitride (SiCN). The dielectric layer 16 may be a high-κ dielectric layer, such as tetraethoxysilane (TEOS) or SiH₄ oxide.

The conductive layer 22 may include conductive materials, such as a metal, a metal silicide, any similar material, or a combination thereof. For example, the metal includes gold (Au), nickel (Ni), platinum (Pt), palladium (Pd), iridium (Ir), titanium (Ti), chromium (Cr), tungsten (W), aluminum (Al), copper (Cu), any similar material, an alloy thereof, or a combination thereof. The conductive layer 22 may be formed by physical vapor deposition, chemical vapor deposition (CVD), atomic layer deposition (ALD), evaporation, sputtering, any similar process, or a combination thereof.

As shown in FIG. 1, in this embodiment, conductive layer 22 includes a lower portion 22A and an upper portion 22B that is connected to and on the lower portion 22A, and the lower portion 22A and the upper portion 22B have different widths (e.g., different diameters). For example, the lower portion 22A has a substantially uniform width, the upper portion 22B has a variable width (e.g., widening from bottom to top), and the width of the lower portion 22A is less than the width of the upper portion 22B, but the present disclosure is not limited thereto.

The support pillars 14A, 14B, 14C, and 14D may include the same or similar material as the isolation layer 10. For example, the support pillars 14A, 14B, 14C, and 14D may include silicon nitride or silicon carbonitride.

Moreover, as shown in FIG. 1, in this embodiment, the support pillars 14A, 14B, 14C, and 14D are connected to the isolation layer 10. In other words, the support pillars 14A, 14B, 14C, and 14D may penetrate through the dielectric layer 16 and be in direct contact with the isolation layer 10, but the present disclosure is not limited thereto. As shown in FIG. 1, in some embodiments, the depth d14 of the support pillars 14A, 14B, 14C, and 14D is from about 100 nm to 200 nm. It should be noted that although the support pillars 14A, 14B, 14C, and 14D are illustrated as having the same depth in FIG. 1, the present disclosure is not limited thereto. In some other embodiments, the support pillars 14A, 14B, 14C, and 14D may also have different or variable depths.

In some embodiments, the material removal rate (MRR) of the dielectric layer 16 is greater than the MRR of the support pillars 14A, 14B, 14C, and 14D. Moreover, as shown in FIG. 1, in this embodiment, the top surface 22T of the conductive layer 22 is aligned with the top surfaces 14T of the support pillars 14A, 14B, 14C, and 14D, but the present disclosure is not limited thereto. In some other embodiments, the top surface 22T of the conductive layer 22 is substantially slightly higher than the top surfaces 14T of the support pillars 14A, 14B, 14C, and 14D.

In some embodiments, the support pillar (e.g., the support pillars 14A, 14B, 14C, and/or 14D shown in FIG. 2A) forms a closed pattern. For example, as shown in the top view of FIG. 2A, the conductive layer 22 may form a circle, and the support pillar 14A and the support pillar 14B are substantially the same component and form a closed circle; the support pillar 14C and the support pillar 14D are substantially the same component and form a closed circle. Furthermore, the support pillars 14A/14B and 14C/14D may form concentric circles. In other embodiments, the support pillars 14A, 14B, 14C, and/or 14D may also form other closed patterns matching the shape of the conductive layer 22, which may be adjusted according to actual needs.

In some embodiments, the support pillar (e.g., support pillars 14A, 14B, 14C, 14D, 14E, 14F, 14G, and/or 14H shown in FIG. 2B) forms a discontinuous pattern that includes multiple segments. For example, as shown in the top view of FIG. 2B, the conductive layer 22 forms a rectangle (e.g., square), and the support pillar 14A, the support pillar 14B, the support pillar 14E, and the support pillar 14F are separated from each other and surround the perimeter of the conductive layer 22, and the support pillar 14C, the support pillar 14D, the support pillar 14G, and the support pillar 14H are separated from each other and surround the perimeter of the conductive layer 22, and outside the support pillar 14A, the support pillar 14B, the support pillar 14E, and the support pillar 14F. In some other embodiments, the support pillars 14A, 14B, 14C, 14D, 14E, 14F, 14G, and/or 14H may also form other discontinuous patterns according to the shape of conductive layer 22, which may be adjusted according to actual needs.

In the embodiments shown in FIG. 2A and FIG. 2B, the semiconductor structure 100 includes multiple support pillars (e.g., the support pillars 14A, 14B, 14C, 14D, 14E, 14F, 14G, and/or 14H), and the support pillars are arranged in sequence from inside to outside with the conductive layer 22 as a center. In some embodiments, in a top view, the shortest distance S between the outermost periphery of the support pillar and the conductive layer 22 is greater than or equal to about 100 nm. For example, as shown in FIG. 2A, the shortest distance S between the conductive layer 22 and the outermost periphery of the support pillars 14C/14D is greater than or equal to about 100 nm; as shown in FIG. 2B, the shortest distance S between the conductive layer 22 and the outermost periphery of the support pillars 14C, 14D, 14G, or 14H is greater than or equal to about 100 nm.

Referring to FIG. 1, FIG. 2A, and FIG. 2B, the semiconductor structure 100 further includes a surface treatment layer 18 and a barrier layer 20. The surface treatment layer 18 is disposed between the conductive layer 22 and the support pillars 14A/14B, and the barrier layer 20 is disposed between the conductive layer 22 and the surface treatment layer 18. For example, the surface treatment layer 18 is formed by treating the dielectric layer 16 (e.g., ashing). That is, the surface treatment layer 18 could originally be a part of dielectric layer 16, but the present disclosure is not limited thereto. In some embodiments, the material removal rate of the surface treatment layer 18 is greater than the material removal rate of the dielectric layer 16.

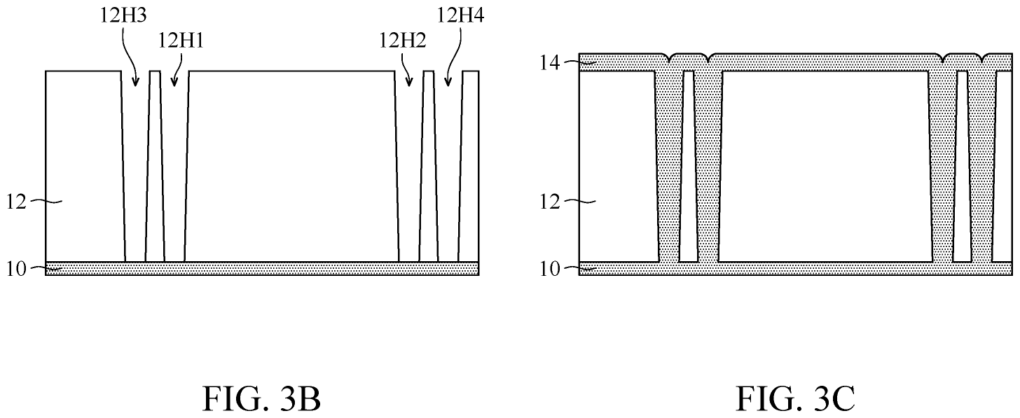

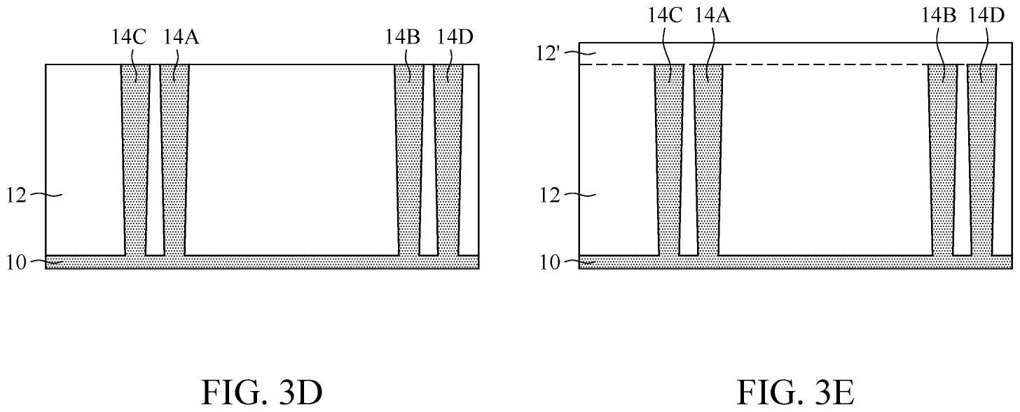

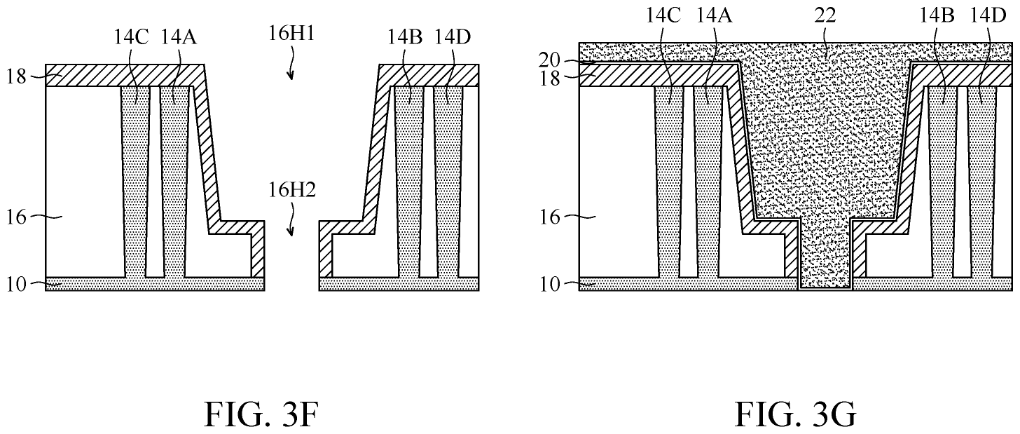

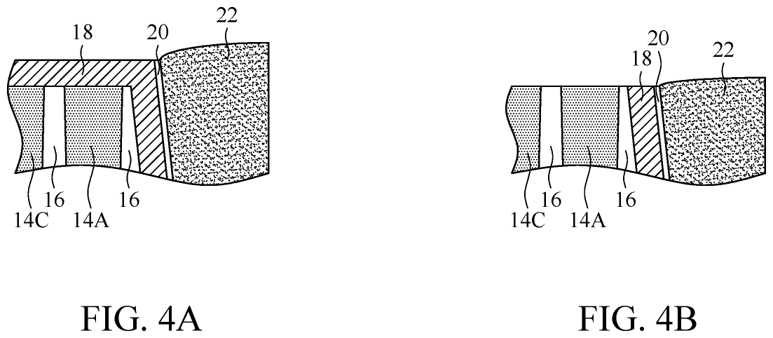

FIG. 3A to FIG. 3G illustrate partial cross-sectional views of forming the semiconductor structure 100 at various stages according to some embodiments of the present disclosure. FIG. 4A to FIG. 4B illustrate partial cross-sectional views from the stage shown in FIG. 3G to an intermediate stage leading to FIG. 1 according to some embodiments of the present disclosure. Similarly, some components of the semiconductor structure 100 have been omitted in FIG. 3A to FIG. 3G and FIG. 4A to FIG. 4B for the sake of brevity.

As shown in FIG. 3A, in some embodiments, a dielectric material 12 is formed on an isolation layer 10. The isolation layer 10 may be, for example, silicon nitride or silicon carbonitride. The dielectric material 12 may be, for example, tetraethyl orthosilicate (TEOS) or SiH₄ oxide. The isolation layer 10 and the dielectric material 12 may be formed by a deposition process, such as CVD, ALD, molecular beam epitaxy (MBE), liquid phase epitaxy (LPE), any similar process, or a combination thereof.

Then, as shown in FIG. 3B, the dielectric material 12 is patterned to form (at least one) trench 12H1, 12H2, 12H3, and 12H4. For example, a mask layer (not shown) may be placed on the dielectric material 12, and then an etching process using the aforementioned mask layer is performed to etch the dielectric material 12 to form the trenches 12H1, 12H2, 12H3, and 12H4. The mask layer may include a photoresist, such as a positive photoresist or a negative photoresist. The mask layer may include a hard mask, and may be formed from materials such as silicon dioxide (SiO₂), silicon nitride, silicon oxynitride (SiON), silicon carbide (SiC), silicon carbonitride, any similar material, or a combination thereof. The mask layer may be a single-layer or multi-layer structure.

The mask layer may be formed by a deposition process, a lithography process, any other appropriate process, or a combination thereof. Here, the deposition process may include spin-on coating, CVD, ALD, any similar process, or a combination thereof. The lithography process may include photoresist coating (e.g., spin-on coating), soft baking, mask aligning, exposure, post-exposure baking (PEB), developing, rinsing, drying (e.g., hard baking), any other suitable process, or a combination thereof.

The etching process may include a dry etching process. For example, the dry etching process may include reactive ion etch (RIE), inductively-coupled plasma (ICP) etching, neutral beam etch (NBE), electron cyclotron resonance (ECR) etching, any similar etching process, or a combination thereof.

As shown in FIG. 3B, the trenches 12H1, 12H2, 12H3, and 12H4 may penetrate through the dielectric material 12 and expose a portion of the surface of the isolation layer 10, but the present disclosure is not limited thereto.

Then, as shown in FIG. 3C, a support material 14 is formed in the trenches 12H1, 12H2, 12H3, and 12H4 (and on the dielectric material 12). For example, the support material 14 may include silicon nitride and be formed by ALD; alternatively, the support material 14 may include silicon carbonitride and be formed by CVD, but the present disclosure is not limited thereto.

Next, as shown in FIG. 3D, a portion of the support material 14 is removed to form support pillars 14A, 14B, 14C, and 14D (in the trenches 12H1, 12H2, 12H3, and 12H4). For example, the portion of the support material 14 may be removed by a wet etching process. The wet etching process may use etchants such as hydrofluoric acid (HF), ammonium hydroxide (NH₄OH), or any suitable etchant. Moreover, in this embodiment, the support pillars 14A, 14B, 14C, and 14D may penetrate through the dielectric material 12 and be in direct contact with the isolation layer 10, but the present disclosure is not limited thereto.

Then, as shown in FIG. 3E, additional dielectric material 12′ is formed on the support pillars 14A, 14B, 14C, 14D, and the dielectric material 12. For example, the additional dielectric material 12′ may include the same or similar material as the dielectric material 12 and may be formed by the same or similar processes, but the present disclosure is not limited thereto. After this step, the overall thickness of the dielectric material (12 or 12′) may be substantially increased.

Next, as shown in FIG. 3F, portions of the dielectric materials 12, 12′ are removed to form a dielectric layer 16 with trenches 16H1 and 16H2 between the support pillar 14A and the support pillar 14B. In other words, the support pillar 14A and the support pillar 14B are outside the trenches 16H1 and 16H2 and surround the trenches 16H1 and 16H2. For example, portions of the dielectric materials 12, 12′ may be removed by a process similar to or the same as that used to form the trenches 12H1, 12H2, 12H3, and 12H4, to form the trenches 16H1 and 16H2. In more detail, a dry etching process may be performed first to form the trench 16H1, followed by another dry etching process to form the trench 16H2.

Moreover, as shown in FIG. 3F, after forming the trenches 16H1 and 16H2, a surface treatment (e.g., ashing process) is performed on the dielectric layer 16 to form a surface treatment layer 18. In other words, the surface treatment layer 18 may, for example, be converted from a portion of the surface of the dielectric layer 16, but the present disclosure is not limited thereto.

Then, as shown in FIG. 3G, a barrier layer 20 and a conductive layer 22 are sequentially formed on the surface treatment layer 18. In more detail, the conductive layer 22 is formed in the trench 16H1 and the trench 16H2 (and on the surface treatment layer 18), so that the support pillar 14A and the support pillar 14B (as well as the support pillar 14C and the support pillar14D) are disposed outside the conductive layer 22 filled into the trench 16H1 and the trench 16H2 and surround the conductive layer 22. The barrier layer 20 and the conductive layer 22 may be formed by a deposition process, the examples of the deposition process have been previously described and will not be repeated here.

After the stage shown in FIG. 3G, a portion of the surface treatment layer 18, a portion of the barrier layer 20, and a portion of the conductive layer 22 are removed to form the semiconductor structure 100 as shown in FIG. 1. For example, the portion of the surface treatment layer 18, the portion of the barrier layer 20, and the portion of the conductive layer 22 may be removed by a CMP process.

As shown in FIG. 4A, after removing the portion of the conductive layer 22 and the portion of the barrier layer 20, and exposing the surface treatment layer 18, due to the higher material removal rate of the surface treatment layer 18, the surface treatment layer 18 may be quickly removed, and the conductive layer 22 may be slightly elevated (protruding) above the surface treatment layer 18 during this process.

Next, as shown in FIG. 4B, after removing the portion of the surface treatment layer 18 and exposing the support pillars 14A, 14C (as well as the support pillars 14B, 14D), due to the lower material removal rate of the support pillars 14A, 14C (and the support pillars 14B, 14D), the support pillars 14A, 14C (and the support pillars 14B, 14D) are not easily removed. Based on the polishing selectivity of the slurry for the dielectric layer 16, the support pillars 14A, 14C (and the support pillars 14B, 14D), and the conductive layer 22, it is possible to control and focus on the removal of parts of the conductive layer 22, making the conductive layer 22 ultimately align with or slightly higher than the support pillars 14A, 14C (and the support pillars 14B, 14D). Thus, the issue of dishing in the conductive layer 22 may be improved, effectively addressing subsequent connection issues and thereby enhancing the overall quality of the semiconductor structure.

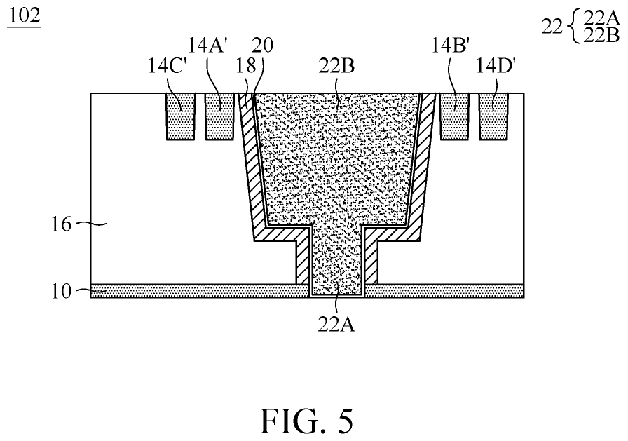

FIG. 5 is a partial cross-sectional view illustrating the semiconductor structure 102 according to some embodiments of the present disclosure. The partial top view of the semiconductor structure 102 may be the same as or similar to the top view shown in FIG. 2A or in FIG. 2B, but the present disclosure is not limited thereto. Moreover, some components of the semiconductor structure 102 have been omitted in FIG. 5 for the sake of brevity.

Referring to FIG. 5, the semiconductor structure 102 includes an isolation layer 10 and a dielectric layer 16 disposed on the isolation layer 10. The semiconductor structure 102 also includes a conductive layer 22 and at least one support pillar (e.g., support pillars 14A′, 14B′, 14C′, and/or 14D′). The conductive layer 22 is disposed in dielectric layer 16, and the support pillars 14A′, 14B′, 14C′, and 14D′ are disposed in dielectric layer 16 and outside the conductive layer 22. In this embodiment, the support pillars 14A′, 14B′, 14C′, and 14D′ surround the conductive layer 22 and are separated from the isolation layer 10. In other words, the support pillars 14A′, 14B′, 14C′, and 14D′ do not completely penetrate through dielectric layer 16.

Similarly, in some embodiments, the semiconductor structure 102 further includes a surface treatment layer 18 and a barrier layer 20. The surface treatment layer 18 is disposed between the conductive layer 22 and the support pillars 14A′/14B′, and the barrier layer 20 is disposed between the conductive layer 22 and the surface treatment layer 18.

In summary, the semiconductor structure according to the embodiment of the present disclosure includes a support pillar. Based on the polishing selectivity of the slurry for the dielectric layer and the support pillar, it is possible to improve the issue of dishing in the conductive layer. This effectively improves subsequent connection issues, thereby enhancing the overall quality of the semiconductor structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. Therefore, the scope of protection should be determined through the claims. In addition, although some embodiments of the present disclosure are disclosed above, they are not intended to limit the scope of the present disclosure.

What is claimed is:

1. A semiconductor structure, comprising:
a dielectric layer;
a conductive layer disposed in the dielectric layer; and
at least one support pillar disposed in the dielectric layer and outside the conductive layer.

2. The semiconductor structure as claimed in claim 1, wherein a material removal rate of the dielectric layer is greater than a material removal rate of the support pillar.

3. The semiconductor structure as claimed in claim 1, wherein in a top view, the support pillar forms a closed pattern.

4. The semiconductor structure as claimed in claim 1, wherein in a top view, the support pillar forms a discontinuous pattern that comprises a plurality of segments.

5. The semiconductor structure as claimed in claim 1, further comprising a plurality of support pillars, wherein the support pillars are arranged in sequence from inside to outside with the conductive layer as a center.

6. The semiconductor structure as claimed in claim 1, further comprising:
an isolation layer disposed below the dielectric layer,
wherein the support pillar is connected to the isolation layer.

7. The semiconductor structure as claimed in claim 1, further comprising:
an isolation layer disposed below the dielectric layer,
wherein the support pillar is separated from the isolation layer.

8. The semiconductor structure as claimed in claim 1, further comprising:
a surface treatment layer disposed between the conductive layer and the support pillar.

9. The semiconductor structure as claimed in claim 8, wherein a material removal rate of the surface treatment layer is greater than a material removal rate of the dielectric layer.

10. The semiconductor structure as claimed in claim 8, further comprising:
a barrier layer disposed between the conductive layer and the surface treatment layer.

11. The semiconductor structure as claimed in claim 1, wherein a top surface of the conductive layer is higher than a top surface of the support pillar or is aligned with the top surface of the support pillar.

12. The semiconductor structure as claimed in claim 1, wherein in a top view, a shortest distance between an outermost periphery of the support pillar and the conductive layer is greater than or equal to 100 nm.

13. The semiconductor structure as claimed in claim 1, wherein a depth of the support pillar is from 100 nm to 200 nm.

14. A method for forming a semiconductor structure, comprising:
forming a dielectric material;
patterning the dielectric material to form at least one first trench;
forming a support pillar in the first trench;
removing a portion of the dielectric material to form a dielectric layer that has a second trench, wherein the support pillar is outside of the second trench; and
forming a conductive layer in the second trench.

15. The method for forming the semiconductor structure as claimed in claim 14, wherein a material removal rate of the dielectric layer is greater than a material removal rate of the support pillar.

16. The method for forming the semiconductor structure as claimed in claim 14, further comprising:
performing a surface treatment on the dielectric layer after forming the second trench to form a surface treatment layer.

17. The method for forming the semiconductor structure as claimed in claim 16, wherein the surface treatment is an ashing process.

18. The method for forming the semiconductor structure as claimed in claim 14, further comprising:
sequentially forming a barrier layer and the conductive layer on the surface treatment layer.

19. The method for forming the semiconductor structure as claimed in claim 14, further comprising:
forming an isolation layer before forming the dielectric material.
